(19) United States
(12) Patent Application Publication
(10) Pub. No.: US 2015/0084490 A1
(43) Pub. Date: Mar. 26, 2015

(54) ELECTRONIC APPARATUS

(71) Applicant: Kabushiki Kaisha Toshiba, Tokyo (JP)

(72) Inventor: Nobuto Fujiwara, Tokyo (JP)

(21) Appl. No.: 14/453,464

(22) Filed: Aug. 6, 2014

Related U.S. Application Data
(60) Provisional application No. 61/882,551, filed on Sep. 25, 2013.

(51) Int. Cl. H05K 7/20; G06F 1/20; G06F 1/16

(52) U.S. Cl. CPC H05K 7/20145; H05K 7/20436; G06F 1/1613; G06F 1/203
USPC 312/236

(57) ABSTRACT

According to one embodiment, an electronic apparatus includes a first housing, a heating component in the first housing, a first heat sink and a fan. The first housing includes a first exhaust hole and a second exhaust hole. The first heat sink faces the first exhaust hole. The first heat pipe thermally connects the heating component and the first heat sink. The fan includes a first discharge hole configured to discharge airflow passing the first heat sink and going to the first exhaust hole, and a second discharge hole configured to discharge airflow passing a circumference of the heating component and going to the second exhaust hole.

### CROSS-REFERENCE TO RELATED APPLICATIONS

This application claims the benefit of U.S. Provisional Application No. 61/882,551, filed Sep. 25, 2013, the entire contents of which are incorporated herein by reference.

### FIELD

Embodiments described herein relate generally to an electronic apparatus.

### BACKGROUND

An electronic apparatus comprising a fan, a heat sink and a heat pipe is provided.

Improvement in cooling performance of electronic apparatuses is required.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective illustration of an electronic apparatus according to one embodiment.

FIG. 2 is a cross-sectional view of the electronic apparatus illustrated in FIG. 1.

FIG. 3 is a back view of the electronic apparatus illustrated in FIG. 1.

FIG. 4 is a bottom view of the electronic apparatus illustrated in FIG. 1.

FIG. 5 is a cross-sectional view of the electronic apparatus illustrated in FIG. 1 (at an opening angle of 0°).

FIG. 6 is a cross-sectional view of the electronic apparatus illustrated in FIG. 1 (at an opening angle of 105°).

FIG. 7 is a cross-sectional view of the electronic apparatus illustrated in FIG. 1 (at an opening angle of 140°).

FIG. 8 is a cross-sectional view taken along line F8-F8 of the electronic apparatus illustrated in FIG. 2.

FIG. 9 is a cross-sectional view illustrating a first modification of the electronic apparatus illustrated in FIG. 1.

FIG. 10 is a back view illustrating a second modification of the electronic apparatus illustrated in FIG. 1.

FIG. 11 is a cross-sectional view illustrating a third modification of the electronic apparatus illustrated in FIG. 1.

FIG. 12 is a cross-sectional view taken along line F12-F12 line of the electronic apparatus illustrated in FIG. 11.

### DETAILED DESCRIPTION

Various embodiments will be described hereinafter with reference to the accompanying drawings.

In general, according to one embodiment, an electronic apparatus comprises a first housing, a heating component in the first housing, a first heat sink and a fan. The first housing comprises a first exhaust hole and a second exhaust hole. The first heat sink faces the first exhaust hole. The first heat pipe thermally connects the heating component and the first heat sink. The fan comprises a first discharge hole configured to discharge airflow passing the first heat sink and going to the first exhaust hole, and a second discharge hole configured to discharge airflow passing a circumference of the heating component and going to the second exhaust hole.

Various embodiments will be described hereinafter with reference to the accompanying drawings.

In this specification, some components are expressed by two or more terms. These terms are merely examples. Those components may be further expressed by another or other terms. And the other components which are not expressed by two or more terms may be expressed by another or other terms.

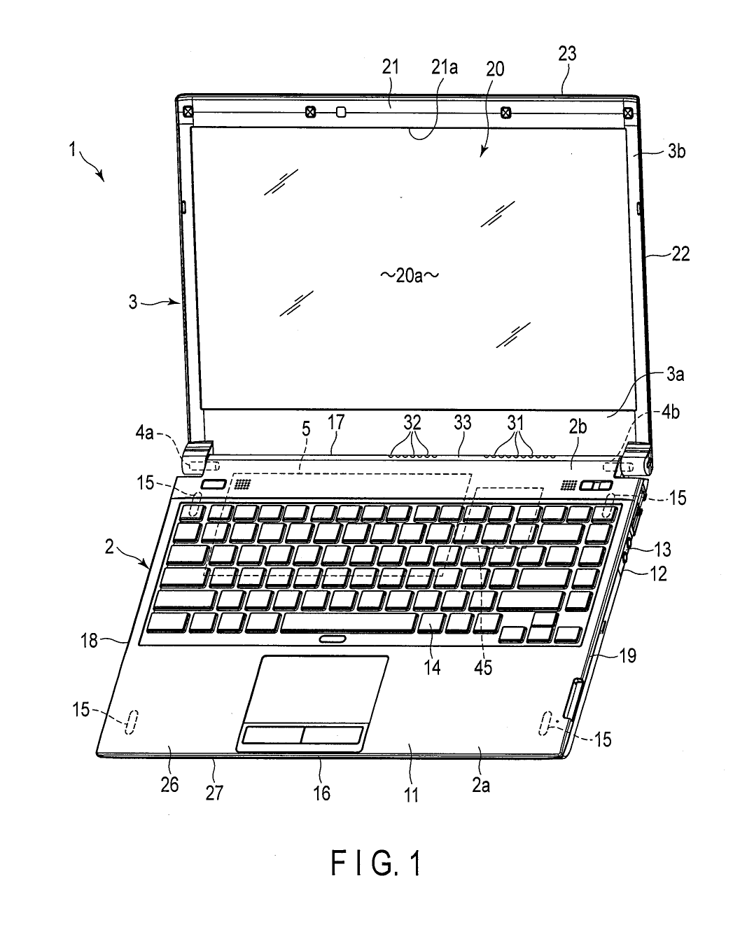

FIG. 1 to FIG. 8 show an electronic apparatus 1 according to one embodiment. The electronic apparatus 1 is, for example, a notebook type of portable computer (i.e., a notebook PC). An electronic apparatus to which the present embodiment is applicable is not limited to the above example. The embodiment is widely applicable to various types of electronic apparatuses such as a television receiver, a tablet type (i.e., a slate type) of portable computer, a cellular phone (including a smartphone) and a game console.

As shown in FIG. 1, the electronic apparatus 1 comprises a first housing 2, a second housing 3 and a pair of hinges 4a and 4b. The first housing 2 is, for example, a main housing. For example, a circuit board 5 as a main board is housed in the first housing 2.

The first housing 2 comprises an upper wall 11, a lower wall 12 (i.e., a bottom wall) and a peripheral wall 13, and is formed into a flat box shape. The upper wall 11 is an example of a first wall. The lower wall 12 is an example of a second wall. In this specification, upper, lower, right and left sides are defined from the perspective of a user. In addition, this specification defines a side close to a user as a front side, and defines a side distant from a user as a rear side.

The upper wall 11 extends longitudinally (e.g., substantially horizontally) with respect to the first housing 2. A keyboard 14 as an input unit is attached to the upper wall 11. The input unit of the upper wall 11 is not limited to a keyboard, and may be, for example, a touchpanel (i.e., a touchsensor) and other input devices.

The lower wall 12 is located on a side opposite to the upper wall 11. The lower wall 12 extends substantially in parallel with, for example, the upper wall 11. When the electronic apparatus 1 is placed on a desk, the lower wall 12 faces the top surface of the desk (i.e., external placement surface). The lower wall 12 comprises, for example, a plurality of legs 15 (i.e., supporters). When the electronic apparatus 1 is placed on a desk, the legs 15 make contact with the top surface of the desk and support the electronic apparatus 1.

The peripheral wall 13 extends in a direction intersecting the upper wall 11 and the lower wall 12, and connects the peripheral edge of the lower wall 12 and the peripheral edge of the upper wall 11. The peripheral wall 13 extends in a thickness direction of the first housing 2. The first housing 2 comprises a first end 2a (e.g., a front end), and a second end 2b (e.g., a rear end) on a side opposite to the first end 2a.

The peripheral wall 13 comprises a front wall 16, a rear wall 17, a left wall 18 and a right wall 19. The front wall 16 is located at the first end 2a, and extends in a right-left direction (i.e., widthwise) of the first housing 2. The rear wall 17 is located at the second end 2b, and extends substantially in parallel with the front wall 16. The rear wall 17 is an example of a third wall. The rear wall 17 extends from the rear end of the upper wall 11 to the rear end of the lower wall 12. The left wall 18 and the right wall 19 extend in a front-back direction (i.e., depthwise) of the first housing 2, and the front-back direction intersects the front wall 16 and the rear wall 17. Each of the left wall 18 and the right wall 19 connects an end of the front wall 16 and an end of the rear wall 17.

The first housing 2 comprises an upper cover 26 (i.e., a cover) and a lower cover 27 (i.e., a base). The upper cover 26 comprises a part of the peripheral wall 13, and the upper wall 11. The lower cover 27 comprises the rest of the peripheral wall 13, and the lower wall 12. The combination of the upper cover 26 and the lower cover 27 forms the first housing 2.

On the other hand, the second housing 3 is, for example, a display housing. A display device 20 (i.e., a display module, a unit) is housed in the second housing 3. A liquid crystal display device is an example of the display device 20. However, the display device 20 is not limited to this example. The display device 20 comprises a display screen 20a configured to display an image.

The second housing 3 comprises a front wall 21 (i.e., a first wall), a rear wall 22 (i.e., a back wall, a second wall) and a peripheral wall 23 (i.e., a sidewall, a third wall), and is formed into a flat box shape. The front wall 21 comprises an opening 21a configured to expose the display screen 20a. The rear wall 22 is located on a side opposite to the front wall 21, and extends substantially in parallel with the front wall 21. The rear wall 22 covers the rear surface of the display device 20. The peripheral wall 23 extends in a direction intersecting the front wall 21 and the rear wall 22, and connects the peripheral edge of the front wall 21 and the peripheral edge of the rear wall 22. The second housing 3 comprises a first end 3a (e.g., a lower end), and a second end 3b (e.g., an upper end) on a side opposite to the first end 3a.

The hinges 4a and 4b rotatably (i.e., openably and closably) attach the second end 2b of the first housing 2 to the first end 3a of the second housing 3. This structure enables the electronic apparatus 1 to be opened and closed (i.e., to be changed in shape, to be folded). The second housing 3 is able to rotate between a first state (e.g., a closed state) and a second state (e.g., an opened state).

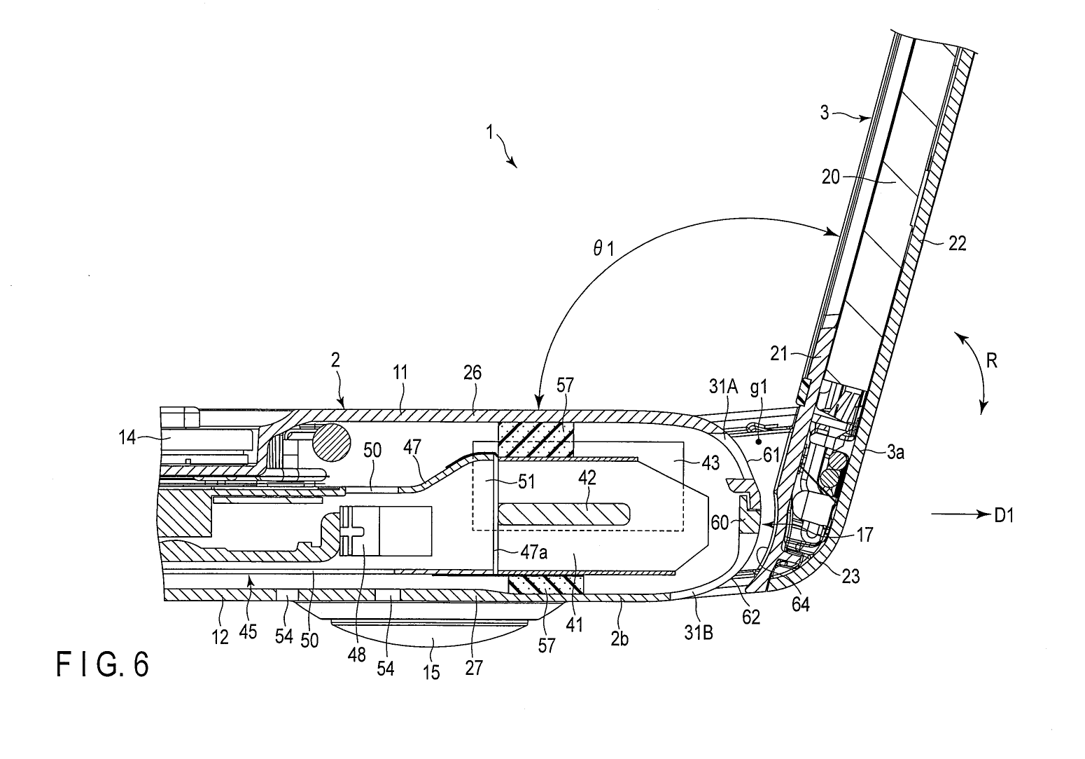

In the first state, the second housing 3 is piled on the first housing 2, and the electronic apparatus 1 is closed. Specifically, the upper wall 11 of the first housing 2 and the front wall 21 of the second housing 3 are overlapped. Further, the display screen 20a and the keyboard 14 are hidden from the outside. On the other hand, in the second state, the second housing 3 stands relative to the first housing 2, and thus the electronic apparatus 1 is open. In the second state, the display screen 20a and the keyboard 14 are exposed to the outside. In addition, in the second state, the first end 3a of the second housing 3 is positioned in horizontally relative to the rear wall 17 of the first housing 2, and faces the rear wall 17 from the back (e.g., see FIG. 6).

Next, a heat dissipation structure of the electronic apparatus 1 is explained.

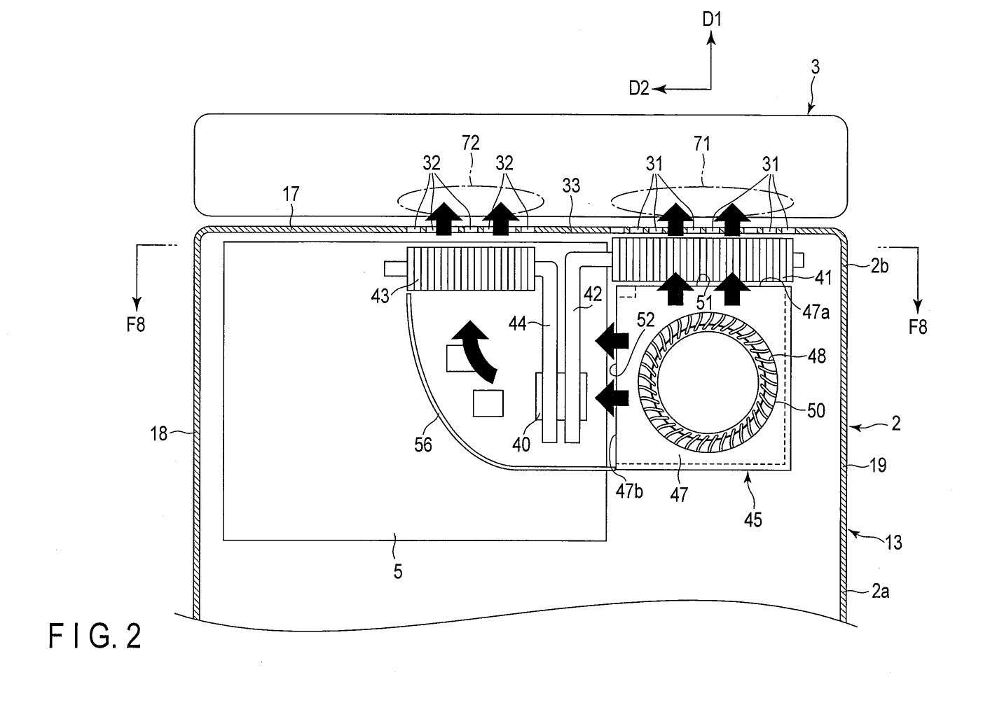

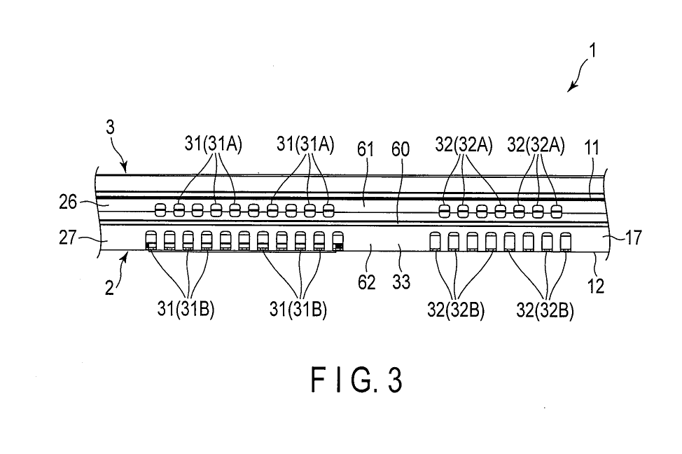

As shown in FIG. 2 and FIG. 3, the first housing 2 comprises a plurality of first exhaust holes 31 and a plurality of second exhaust holes 32. The first exhaust holes 31 and the second exhaust holes 32 are both provided in the rear wall 17 of the first housing 2, and open toward the same direction.

The plurality of first exhaust holes 31 and the plurality of second exhaust holes 32 are separately provided in a longitudinal direction (e.g., a right-left direction) of the rear wall 17. The plurality of first exhaust holes 31 are arranged in line in the longitudinal direction of the rear wall 17. The plurality of second exhaust holes 32 are arranged in line in the longitudinal direction of the rear wall 17.

A closed portion 33 is provided between the plurality of first exhaust holes 31 and the plurality of second exhaust holes 32. The closed portion 33 is larger than, for example, the first exhaust hole 31 or the second exhaust hole 32. The closed portion 33 is larger than, for example, the length of a side of a heating component 40 explained later.

As illustrated in FIG. 2, the heating component 40 is mounted on the circuit board 5. The heating component 40 is, for example, a CPU or a graphics chip. However, the heating component 40 is not limited to these examples. A first heat sink 41, a first heat pipe 42, a second heat sink 43, a second heat pipe 44 and a fan 45 are housed in the first housing 2.

The first heat sink 41 is provided as a separate unit from the fan 45, and faces the plurality of first exhaust holes 31. The first heat sink 41 is a fin unit in which a plurality of fins are allocated in line. The first heat sink 41 is located on a lateral side of the circuit board 5, and does not overlap the circuit board 5 in the thickness direction of the first housing 2.

The first heat pipe 42 extends between the heating component 40 and the first heat sink 41, and thermally connects the heating component 40 and the first heat sink 41. In this structure, the heat generated by the heating component 40 when the electronic apparatus 1 is used is partially transferred to the first heat sink 41 by the first heat pipe 42. In sum, the first remote heat exchange (RHE) type of heat dissipation structure is realized by the first heat sink 41, the first heat pipe 42 and the fan 45.

The second heat sink 43 is provided as a separate unit from the fan 45 at a position away from the fan 45, and faces the plurality of second exhaust holes 32. The second heat sink 43 is a fin unit in which a plurality of fins are arranged in line. The second heat sink 43 is located on the upper side (or the lower side) of the circuit board 5, and overlaps the circuit board 5 in the thickness direction of the first housing 2.

The second heat pipe 44 extends between the heating component 40 and the second heat sink 43, and thermally connects the heating component 40 and the second heat sink 43. In this structure, the heat generated by the heating component 40 at the time of using the electronic apparatus 1 is partially transferred to the second heat sink 43 by the second heat pipe 44. Thus, the second remote heat exchange (RHE) type of heat dissipation structure is realized by the second heat sink 43, the second heat pipe 44 and the fan 45.

As shown in FIG. 2, the fan 45 (i.e., a cooling fan) is a centrifugal fan of bidirectional exhaust, and is provided near the second end 2b of the first housing 2. The fan 45 is lateral to the circuit board 5, and does not overlap the circuit board 5 in the thickness direction of the first housing 2. The fan 45 comprises a fan case 47, and an impeller 48 which is rotated and driven within the fan case 47. The fan case 47 comprises a suction hole 50, a first discharge hole 51 and a second discharge hole 52.

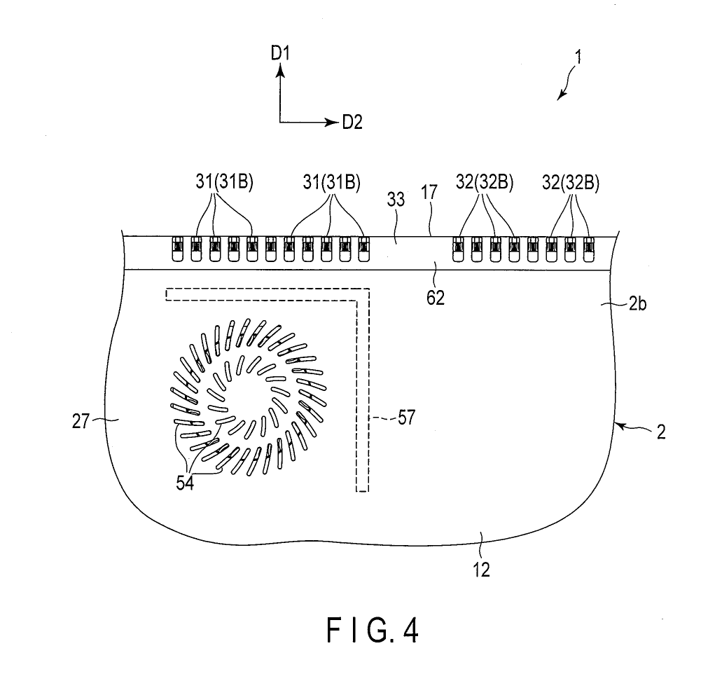

The suction hole 50 opens on the upper and lower surfaces of the fan case 47. The suction hole 50 of the lower surface of the fan case 47 faces the lower wall 12 of the first housing 2. The lower wall 12 of the first housing 2 comprises a plurality of intake holes 54 facing the suction hole 50 of the fan 45 (refer to FIG. 4). The fan 45 draws outer air (i.e., fresh air) of the first housing 2 through the intake holes 54 of the lower wall 12.

As illustrated in FIG. 2, the first discharge hole 51 of the fan 45 is provided on a first side surface 47a of the fan case 47, and opens toward the rear wall 17. The first discharge hole 51 faces the first heat sink 41 and the plurality of first exhaust holes 31. The first discharge hole 51 discharges airflow directed to the first exhaust holes 31 through the first heat sink 41. In other words, the first discharge hole 51 discharges airflow in a direction (i.e., a first direction D1) toward the rear wall 17 from the fan 45.

On the other hand, the second discharge hole 52 is provided on a second side surface 47b which is different from the first side surface 47a in the fan case 47. The second discharge hole 52 opens toward a direction which is different from, for example, the first discharge hole 51 by substantially 90 degrees. The second discharge hole 52 discharges airflow in a second direction D2 intersecting (e.g., substantially orthogonal to) the first direction D1.

The second discharge hole 52 faces the heating component 40 mounted on the circuit board 5. The second discharge hole 52 discharges airflow toward the heating component 40. Specifically, the second discharge hole 52 discharges airflow which passes the circumference of the heating component 40 and then goes to the second exhaust holes 32 through the second heat sink 43.

In the present embodiment, the heating component 40 is located between the second discharge hole 52 and the second exhaust holes 32. As shown in FIG. 2, a guide 56 (e.g., a duct) is provided within the first housing 2. The guide 56 guides the airflow which passed the circumference of the heating component 40 so as to head for the second exhaust holes 32. The guide 56 leads the airflow discharged from the second discharge hole 52 of the fan 45 in the second direction D2 to the first direction D1. The guide 56 may be formed by sponge located between the circuit board 5 and the inner surface of the first housing 2, a rib provided in the inner surface of the first housing 2, or the combination of the sponge and the rib. However, the guide 56 is not limited to these examples.

According to the above heat dissipation structure, by driving the fan 45, airflow is discharged from the first discharge hole 51 toward the first heat sink 41. This airflow takes heat from the first heat sink 41 during a process passing through the first heat sink 41. After that, the airflow is discharged from the first exhaust holes 31 to the outside of the first housing 2.

On the other hand, airflow is discharged directly toward the heating component 40 from the second discharge hole 52. This airflow directly takes heat from the heating component 40 by moving around the heating component 40. The airflow which passed the circumference of the heating component 40 is guided to the second heat sink 43 by the guide 56. This airflow takes heat from the second heat sink 43 during a process passing through the second heat sink 43. After that, the airflow is discharged from the second exhaust holes 32 to the outside of the first housing 2. Thus, heat release of the heating component 40 is accelerated.

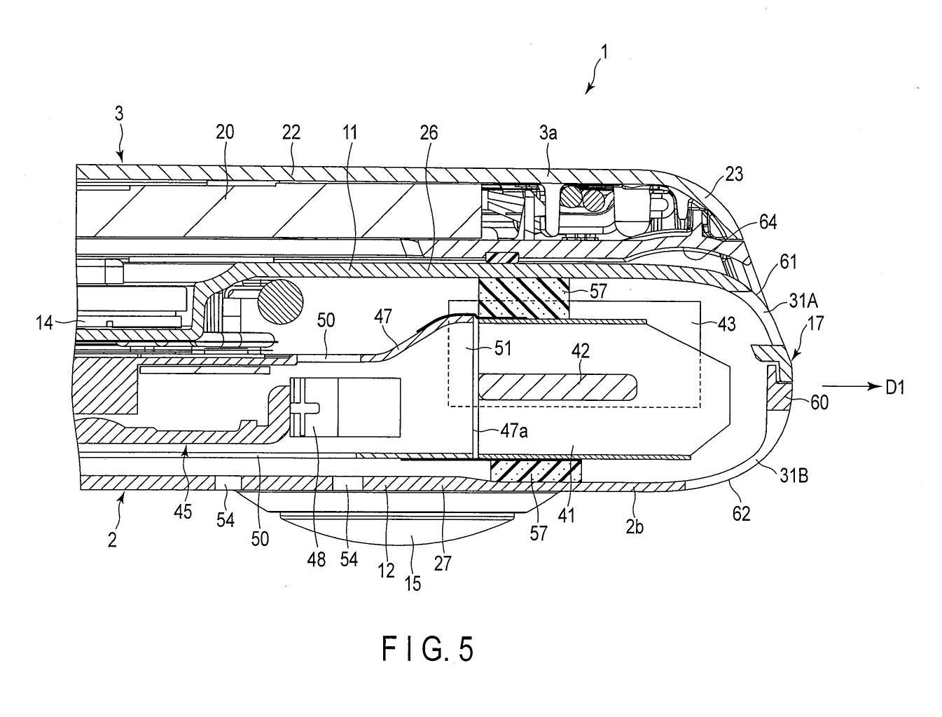

As shown in FIG. 4 and FIG. 5, an airflow shield 57 is provided inside the first housing 2. The airflow shield 57 is provided in order to block or reduce the air flow between the suction hole 50 and the discharge hole 51 or 52. In this structure, the airflow discharged from the first or second discharge hole 51 or 52 is not absorbed into the fan 45 again before the airflow is discharged to the outside of the first housing 2.

Next, the first and second exhaust holes 31 and 32 are explained in detail. As illustrated in FIG. 2 and FIG. 6, the first and second exhaust holes 31 and 32 are provided in the rear wall 17 of the first housing 2. Therefore, the first and second exhaust holes 31 and 32 face (e.g. are covered by) the second housing 3 when the second housing 3 is raised with respect to the first housing 2.

As shown in FIG. 5, the rear wall 17 of the first housing 2 is formed into, for example, a circular arc shape ranging from the end of the upper wall 11 to the end of the rear wall 17. Specifically, the rear wall 17 comprises an outmost portion 60 (e.g., a central portion), a first area 61 (e.g., an upper area) and a second area 62 (e.g., a lower area). The outmost portion 60 is located at the outermost position of the rear wall 17 in the direction from the fan 45 toward the rear wall 17. The outmost portion 60 extends substantially across the full width of the first housing 2 along the longitudinal direction of the rear wall 17. The outmost portion 60 includes a connected portion (e.g., a border, a joint surface) of the upper cover 26 and the lower cover 27.

The first area 61 extends between the outmost portion 60 and the upper wall 11. The first area 61 extends, inclining toward the upper wall 11 from the outmost portion 60. The second area 62 is located at a side opposite to the first area 61 relative to the outmost portion 60. The second area 62 extends between the outmost portion 60 and the lower wall 12. The second area 62 extends, inclining toward the lower wall 12 from the outmost portion 60.

In other words, the first area 61 and the second area 62 extend from the outmost portion 60 to opposite sides to each other (e.g., to the upper side and the lower side). Both of the first area 61 and the second area 62 incline toward the central side of the first housing 2. In this specification, “to incline” refers to inclination relative to the thickness direction (e.g., substantially vertical direction) of the first housing 2. In the present embodiment, the first area 61 and the second area 62 bend in a circular arc shape. However, the first area 61 and the second area 62 are not limited to this structure, and may be inclined surfaces which extend, for example, linearly inclining.

As illustrated in FIG. 3 and FIG. 5, the plurality of first exhaust holes 31 include a plurality of first upper exhaust holes 31A (i.e., first holes) provided in the first area 61, and a plurality of first lower exhaust holes 31B (i.e., second holes) provided in the second area 62. The plurality of first upper exhaust holes 31A are arranged in line in the longitudinal direction of the rear wall 17, and the plurality of first lower exhaust holes 31B are also arranged in line in the longitudinal direction of the rear wall 17.

The plurality of first upper exhaust holes 31A and the plurality of first lower exhaust holes 31B are provided in a zigzag manner (i.e., in a staggered pattern) with respect to each other in such a way that the holes are alternately positioned along the longitudinal direction of the rear wall 17. Thus, the plurality of first upper exhaust holes 31A do not overlap (or less overlap) the plurality of first lower exhaust holes 31B in the thickness direction of the first housing 2. This structure improves strength of the first housing 2. Further, when the first housing 2 is looked from above, the first lower exhaust holes 31B are difficult to be seen through the first upper exhaust holes 31A. In this manner, the design of the electronic apparatus 1 can be improved.

As illustrated in FIG. 5, the first upper exhaust holes 31A are located above the outmost portion 60. The first upper exhaust holes 31A are provided in the first area 61 extending at a tilt. Thus, the first upper exhaust holes 31A open on the rear side and upper side of the first housing 2. The phrase “open on the upper side” means that the holes can be seen when they are looked from the direction perpendicular to the upper wall 11.

On the other hand, the first lower exhaust holes 31B are located below the outmost portion 60. The first lower exhaust holes 31B are provided in the second area 62 extending at a tilt, and open on the rear side and lower side of the first housing 2. The phrase “open on the lower side” means that the holes can be seen when they are looked from the direction perpendicular to the lower wall 12.

The first lower exhaust holes 31B are larger than, for example, the first upper exhaust holes 31A. The first lower exhaust holes 31B are long holes which are longer than the first upper exhaust holes 31A. The lower ends of the first lower exhaust holes 31B reach a position equal to the lower wall 12 in a direction from the fan 45 toward the rear wall 17 (e.g., a direction substantially parallel to the lower wall 12, or a substantially horizontal direction).

As shown in FIG. 3, similarly to the first exhaust holes 31, the plurality of second exhaust holes 32 include a plurality of second upper exhaust holes 32A (i.e., first holes) provided in the first area 61, and a plurality of second lower exhaust holes 32B (i.e., second holes) provided in the second area 62. The plurality of second upper exhaust holes 32A are allocated in line in the longitudinal direction of the rear wall 17. The plurality of second lower exhaust holes 32B are also arranged in line in the longitudinal direction of the rear wall 17.

The plurality of second upper exhaust holes 32A and the plurality of second lower exhaust holes 32B are provided in a zigzag manner (i.e., in a staggered pattern) with respect to each other in such a way that the holes are alternately positioned along the longitudinal direction of the rear wall 17. Therefore, the plurality of second upper exhaust holes 32A do not overlap or less overlap the second lower exhaust holes 32B in the thickness direction of the first housing 2. In this structure, strength of the first housing 2 is improved. Further, when the first housing 2 is looked from above, the second lower exhaust holes 32B are difficult to be seen through the second upper exhaust holes 32A. Thus, the design of the electronic apparatus 1 can be improved.

The position, shape and size of the second upper exhaust holes 32A are the same as, for example, the first upper exhaust holes 31A. The position, shape and size of the second lower exhaust holes 32B are the same as, for example, the first lower exhaust holes 31B. Therefore, detailed explanation of the second upper exhaust holes 32A or the second lower exhaust holes 32B is omitted.

The above descriptions can be rephrased as follows. The first exhaust holes 31 include a portion located in one of the first area 61 and the second area 62. The second exhaust holes 32 include a portion located in the other one of the first area 61 and the second area 62. The first exhaust holes 31 may be provided in only one of the first area 61 and the second area 62. In short, the first exhaust holes 31 may be only the first upper exhaust holes 31A, or only the first lower exhaust holes 31B.

The second exhaust holes 32 may be provided in only one of the first area 61 and the second area 62. In other words, the second exhaust holes 32 may be only the second upper exhaust holes 32A, or only the second lower exhaust holes 32B. The number of first exhaust holes 31 or second exhaust holes 32 is not need to be more than one. For example, one hole may be employed as each of the member “first exhaust holes 31” and the member “second exhaust holes 32”.

Next, the positional relationships of the second housing 3 with the first exhaust holes 31 and the second exhaust holes 32 are explained.

FIG. 6 illustrates the electronic apparatus 1 at a first opening angle of θ1. The first opening angle of θ1 is, for example, an opening angle when the electronic apparatus 1 is ordinarily used. The first opening angle of θ1 is, for example, 100 to 110°.

At the first opening angle of θ1, the second housing 3 faces the first and second upper exhaust holes 31A and 32A from the rear side, but does not cover at least a part (e.g., the lower portion) of the first and second lower exhaust holes 31B and 32B. The second housing 3 does not cover the lower portion of the first and second lower exhaust holes 31B and 32B. In other words, the first and second lower exhaust holes 31B and 32B open downward. Therefore, part of the airflow moving from the fan 45 to the rear wall 17 is effectively discharged from the first and second lower exhaust holes 31B and 32B.

A recess 64 facing the rear wall 17 of the first housing 2 is provided at the first end 3a of the second housing 3. The recess 64 is depressed in a circular arc shape along the rear wall 17 of the first housing 2. By the placement of the recess 64, a certain gap is ensured at all times between the first lower exhaust holes 31B and the second housing 3, and between the second lower exhaust holes 32B and the second housing 3. Therefore, part of the airflow moving from the fan 45 to the rear wall 17 is easily discharged from the first and second lower exhaust holes 31B and 32B. In addition, there is a gap between the first upper exhaust holes 31A and the second housing 3, and between the second upper exhaust holes 32A and the second housing 3. Thus, part of the airflow heading from the fan 45 for the rear wall 17 can be also discharged from the first and second upper exhaust holes 31A and 32A.

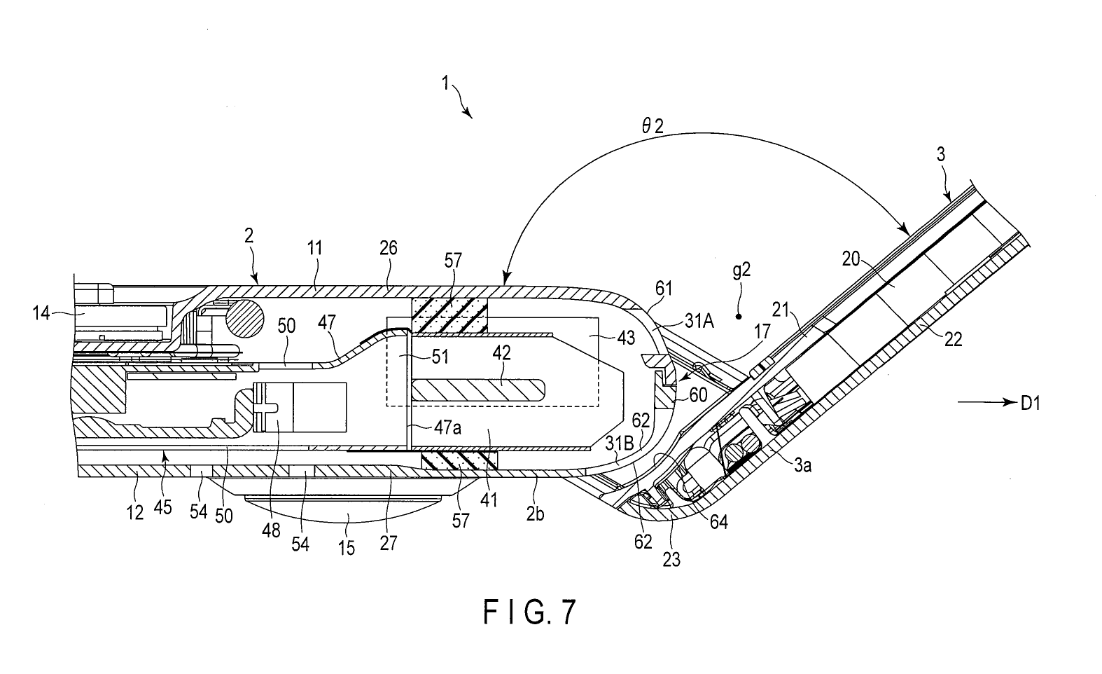

On the other hand, FIG. 7 shows the electronic apparatus 1 at a second opening angle of θ2. At the second opening angle of θ2, the second housing 3 is largely rotated in such a way that, for example, several people can look at a screen. The second opening angle of θ2 is larger than the first opening angle of θ1. The second opening angle of θ2 is, for example, 140°. However, the second opening angle of θ2 is not limited to this example.

At the second opening angle of θ2, the first end 3a of the second housing 3 is located obliquely below the first and second lower exhaust holes 31B and 32B. The first end 3a of the second housing 3 faces, for example, substantially the whole area of the first and second lower exhaust holes 31A and 32B from rearward and downward. On the other hand, a gap g2 between the second housing 3 and each of the first and second upper exhaust holes 31A and 32A is larger than a gap g1 between the second housing 3 and each of the first and second upper exhaust holes 31A and 32A at the first opening angle of θ1. The gap g2 between the second housing 3 and each of the first and second upper exhaust holes 31A and 32A is larger than, for example, a gap between the first sink 41 and the rear wall 17.

Therefore, part of the airflow moving from the fan 45 to the rear wall 17 is effectively discharged from the first and second upper exhaust holes 31A and 32A. By the placement of the recess 64 in the second housing 3, a gap is also provided between the second housing 3 and each of the first and second lower exhaust holes 31B and 32B. Thus, part of the airflow going from the fan 45 to the rear wall 17 can be also discharged from the first and second lower exhaust holes 31B and 32B.

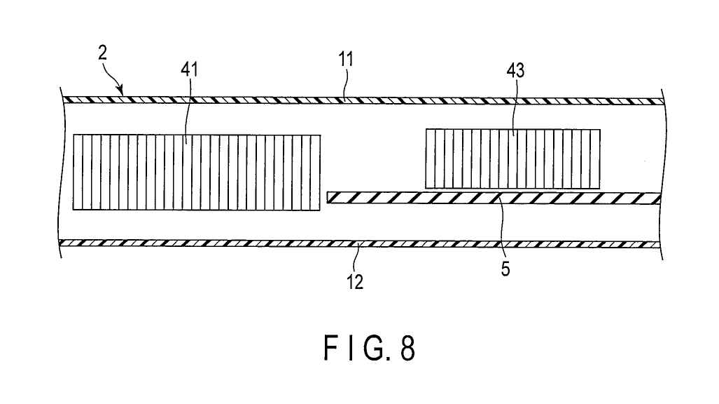

As shown in FIG. 8, the second heat sink 43 overlaps the circuit board 5 in the thickness direction of the first housing 2. This differentiates the height of the first heat sink 41 from the height of the second heat sink 43 within the first housing 2.

In sum, as illustrated in FIG. 6, the first heat sink 41 and the second heat sink 43 are provided in such a way that they are out of alignment each other in a rotation direction R of the second housing 3. In other words, the first heat sink 41 and the second heat sink 43 are provided at positions shifted from each other in the thickness direction of the first housing 2 (i.e., a direction from the upper wall 11 to the lower wall 12).

The first heat sink 41 faces, for example, the first upper exhaust holes 31A and the first lower exhaust holes 31B. The second heat sink 43 faces, for example, the second upper exhaust holes 32A. In the present embodiment, the overlapped area of the second heat sink 43 and the second upper exhaust holes 32A in the first direction D1 is larger than the overlapped area of the first heat sink 41 and the first upper exhaust holes 31A in the first direction D1.

The second heat sink 43 may face the second lower exhaust holes 32B, in addition to the second upper exhaust holes 32A or instead of the second upper exhaust holes 32A. The first heat sink 41 may face only the first upper exhaust holes 31A or only the first lower exhaust holes 31B.

According to the electronic apparatus 1 having the above structure, heat release performance can be improved.

In recent years, electronic apparatuses have been thinner. Therefore, the size and thickness of fans and heat sinks need to be reduced. Thus, there is a possibility that cooling performance is insufficient.

The electronic apparatus 1 of the present embodiment comprises the first housing 2, the heating component 40 housed in the first housing 2, the first heat sink 41, the first heat pipe 42 and the fan 45. The first housing 2 comprises the first exhaust holes 31 and the second exhaust holes 32. The first heat sink 41 faces the first exhaust holes 31. The first heat pipe 42 thermally connects the heating component 40 and the first heat sink 41. The fan 45 comprises the first discharge hole 51 which discharges airflow passing the first heat sink 41 and going to the first exhaust holes 31, and the second discharge hole 52 which discharges airflow passing the circumference of the heating component 40 and going to the second exhaust holes 32.

According to this structure, it is possible to increase the opening area of the discharge holes of the fan 45, and increase the entire amount of discharged airflow as compared to a fan which has only one discharge hole and is the same in size. By using this increased airflow volume, airflow is discharged from the first discharge hole 51 to the first heat sink 41, and further, airflow is discharged from the second discharge hole 52 directly to the heating component 40. In this manner, it is possible to effectively promote cooling of the heating component 40. Thus, the cooling performance of the electronic apparatus 1 can be enhanced. In addition, if the cooling performance of the electronic apparatus 1 is enhanced, the cooling device of the fan 45 and the heat sink 41, etc. can be downsized. Thus, the size and the thickness of the electronic apparatus can be reduced.

Moreover, according to the above structure, the airflow which passed the first heat sink 41 is discharged from the first exhaust hole 31 to the outside of the first housing 2. On the other hand, the airflow which passed the circumference of the heating component 40 is discharged from the second exhaust holes 32 to the outside of the first housing 2. Therefore, even if either one of a group of first exhaust holes 31 and a group of second exhaust holes 32 is blocked for some reason, it is possible to promote cooling of the heating component 40 by discharging airflow from the other one of a group of first exhaust holes 31 and a group of second exhaust holes 32.

In other words, for example, if the first exhaust holes 31 are blocked, the heating component 40 can be cooled down by the airflow which is discharged from the second discharge hole 52 of the fan 45, passes the circumference of the heating component 40 and is discharged from the second exhaust holes 32. For example, if the second exhaust holes 32 are blocked, the heating component 40 can be cooled down by the airflow which is discharged from the first exhaust hole 51 of the fan 45, passes through the first heat sink and is discharged from the first exhaust holes 31. Thus, the heat release of the heating component 40 is maintained. In this manner, the cooling performance of the electronic apparatus 1 can be stabilized.

In the present embodiment, the electronic apparatus 1 further comprise the second heat sink 43 facing the second exhaust holes 32. The airflow from the second discharge hole 52 passes the circumference of the heating component 40, passes through the second heat sink 43 and moves to the second exhaust holes 32. According to this structure, by using the airflow directly blowing against the heating component 40, the cooling performance of the electronic apparatus 1 can be further improved.

In the present embodiment, the electronic apparatus 1 further comprises the second heat pipe 44 which thermally connects the heating component 40 and the second heat sink 43. According to this structure, by using the airflow directly blowing against the heating component 40, the cooling of the heating component 40 can be further enhanced. This contributes to the improvement of the cooling performance of the electronic apparatus 1.

In the present embodiment, the electronic apparatus 1 further comprises the second housing 3 rotatably attached to the first housing 2. The first housing 2 comprises the first wall (e.g., the upper wall 11), the second wall (e.g., the lower wall 12) located on a side opposite to the first wall, and the third wall (e.g., the rear wall 17) which ranges over the first wall and the second wall and faces the second housing 3 when the second housing 3 is raised with respect to the first housing 2. The first exhaust holes 31 and the second exhaust holes 32 are provided in the third wall, and face the second housing 3 standing relative to the first housing 2.

For example, when an exhaust hole is provided in the rear wall of the first housing in a general electronic apparatus, the exhaust hole is covered by the second housing. Thus, through the reduction in the exhaust efficiency, the cooling performance might be reduced. However, in the electronic apparatus of the present embodiment, the number of exhaust holes is increased by the provision of the second exhaust holes 32 in addition to the first exhaust holes 31. Therefore, even if the first exhaust holes 31 and the second exhaust holes 32 are covered by the second housing 3, and thus exhaust efficiency of each hole is reduced, it is possible to ensure cooling efficiency sufficient to cool the electronic apparatus 1 in terms of the total exhaust amount of the first exhaust holes 31 and the second exhaust holes 32. In this manner, the cooling performance of the electronic apparatus 1 can be improved.

A connector, etc. cannot be provided in the rear wall 17 of the first housing 2 since the second housing 3 faces the rear wall 17 when the second housing 3 is raised with respect to the first housing 2. In the structure of the present embodiment, the number of exhaust holes is increased by utilizing the rear wall 17 of the first housing 2. Generally, the rear wall 17 easily becomes dead space. Therefore, even if the number of exhaust holes is increased, it is possible to avoid enlarging the size of the electronic apparatus 1.

In the present embodiment, the third wall comprises a portion (e.g., the outmost portion 60) located at the outermost position of the third wall in the direction from the fan 45 to the third wall, the first area 61 which inclines from the portion toward the first wall and extends, and the second area 62 which inclines from the portion toward the second wall. The first exhaust holes 31 include a portion located in one of the first area 61 and the second area 62. The second exhaust holes 32 include a portion located in the other one of the first area 61 and the second area 62.

According to this structure, even if the second housing 3 is at any opening state, exhaust holes on one side (i.e., the first exhaust holes 31 or the second exhaust holes 32) are always open. Therefore, even if the exhaust holes 31 and 32 are provided in the rear wall 17 of the first housing 2 covered by the second housing 3, effective exhaust is possible, and thus, the cooling performance of the electronic apparatus 1 can be improved.

In the present embodiment, at the first opening angle of θ1, the second housing 3 faces the first and second upper exhaust holes 31A and 32A, and does not cover at least a part of the first and second lower exhaust holes 31B and 32B. Therefore, at the first opening angle of θ1, the airflow from the fan 45 can be effectively discharged from the first and second lower exhaust holes 31B and 32B.

In the present embodiment, at the second opening angle of θ2 which is larger than the first opening angle of θ1, the second housing 3 faces the first and second lower exhaust holes 31B and 32B. The gap g2 between the second housing 3 and each of the first and second upper exhaust holes 31A and 32A is larger than the gap g1 between the second housing 3 and each of the first and second upper exhaust holes 31A and 32A at the first opening angle of el. Therefore, at the second opening angle of θ2, the airflow from the fan 45 can be effectively discharged from the first and second upper exhaust holes 31A and 32A.

In the present embodiment, the first heat sink 41 and the second heat sink 43 are provided at positions shifted from each other along the rotation direction of the second housing 3 (or along the thickness direction of the first housing 2). According to this structure, even if one of the upper exhaust holes 31A and 32A and the lower exhaust holes 31B and 32B is covered by the second housing 3, at least one of the first heat sink 41 and the second heat sink 43 effectively functions. Thus, it is possible to minimize the influence from the airflow amount reduction caused by the structure in which the second housing 3 covers the first exhaust holes 31 and the second exhaust holes 32. In this manner, the cooling performance of the electronic apparatus 1 can be stabilized.

In the present embodiment, the second discharge hole 52 opens in a direction which is different from the first discharge hole 51. The electronic apparatus 1 further comprises the guide 56 provided in the first housing 2. The guide 56 guides airflow which was discharged from the second discharge hole 52 and passed the circumference of the heating component 40 so as to go to the second exhaust holes 32. According to this structure, the airflow directly blowing against the heating component 40 can be effectively guided to the second exhaust holes 32. Thus, the cooling performance of the electronic apparatus 1 can be further improved.

The second heat sink 43 may be unnecessary. The second heat sink 43 may be thermally connected to a heating component which is different from the heating component 40 thermally connected to the first heat sink 41.

Next, the structure of the present embodiment is explained from another point of view.

For comparison, this specification now considers an electronic apparatus comprising a unidirectional exhaust fan in which an exhaust hole is provided in the rear wall of the first housing covered by the second housing, and airflow blows toward the exhaust hole. In this case, heat generated within the first housing 2 is mostly and intensively discharged from the above exhaust hole.

Therefore, a portion of the second housing faces the above exhaust hole and intensively receives heat. Thus, local elevation of temperature might arise in a part of the second housing. For example, on the condition that the electronic apparatus 1 of FIG. 2 does not comprise the second exhaust holes 32, the airflow from the fan 45 might intensively hit a first portion 71 of the second housing 3, the first portion 71 facing the first exhaust holes 31. Thus, the temperature of the first portion 71 might locally rise. This local elevation of temperature might have a bad influence on components housed in the second housing 3.

On the other hand, the electronic apparatus 1 of the present embodiment comprises the first housing 2, the second housing 3, the first heat sink 41, the heating component 40 housed in the first housing 2, and the fan 45. The first housing 2 comprises the first exhaust holes 31 and the second exhaust holes 32. The second housing 3 is rotatably attached to the first housing 2, and faces the first exhaust holes 31 and the second exhaust holes 32 when the second housing 3 stands relative to the first housing 2. The first heat sink 41 faces the first exhaust holes 31. The fan 45 comprises the first discharge hole 51 configured to discharge airflow which passes the first heat sink 41 and goes to the first exhaust holes 31. The fan 45 further comprises the second discharge hole 52 configured to discharge airflow which passes the circumference of the heating component 40 and goes to the second exhaust holes 32.

According to this structure, the airflow which was discharged from the first discharge hole 51 and took heat from the heat sink 41 is discharged from the first exhaust holes 31 and hits the first portion 71 of the second housing 3, the first portion 71 facing the first exhaust holes 31. On the other hand, the airflow which was discharged from the second discharge hole 52 and directly took heat from the heating component 40 is discharged from the second exhaust holes 32, and hits a second portion 72 of the second housing 3, the first portion 71 facing the second exhaust holes 32. Thus, the heat generated within the first housing 2 separately has an influence on the first portion 71 and the second portion 72 of the second housing 3. Therefore, it is possible to avoid local elevation of temperature within the second housing 3, and equalize the heat within the second housing 3. In this manner, the cooling performance of the electronic apparatus 1 can be improved. Further, the reliability and lifetime of the electronic apparatus 1 can be improved.

In particular, when the first heat sink 41 is connected to the heating component 40, the heat from the heating component 40 can be divided into the first portion 71 and the second portion 72 of the second housing 3. Therefore, the equalization of heat of the second housing 3 can be further improved.

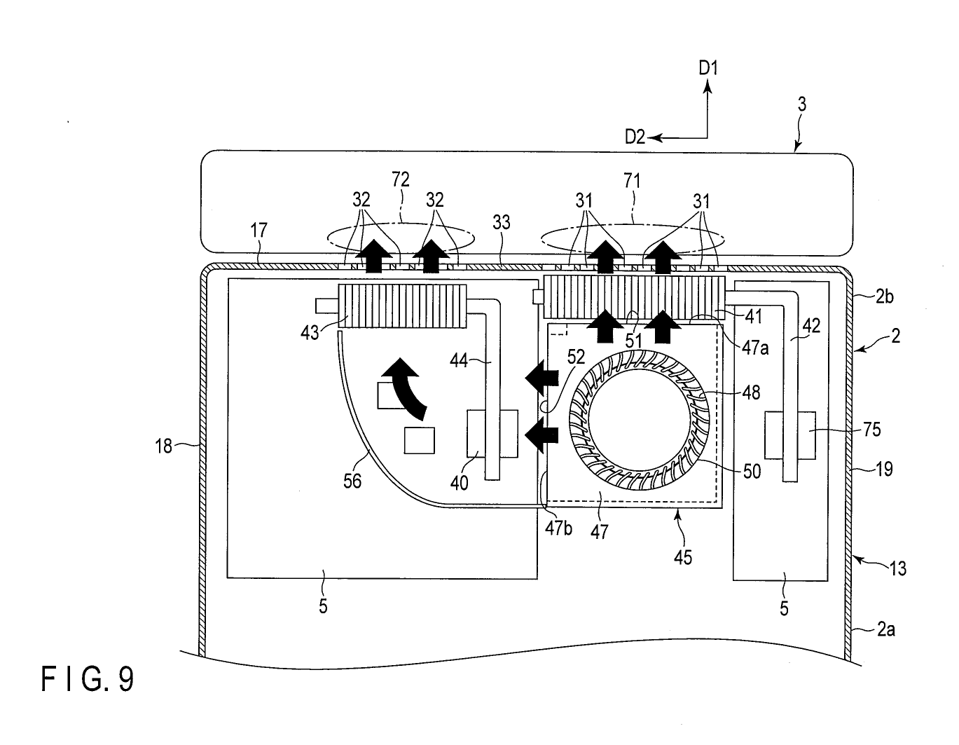

In a case of this point of view, the first heat sink 41 may not be thermally connected to the heating component 40. For example, as shown in FIG. 9, the first heat sink 41 may be thermally connected to a heating component 75 which is different from the heating component 40.

In the present embodiment, the electronic apparatus 1 further comprises the second heat sink 43 facing the second exhaust holes 32. The airflow from the second discharge hole 52 passes the circumference of the heating component 40, and then goes through the second heat sink 43 to the second exhaust holes 32. According to this structure, the heat from the first heat sink 41 and the heat from the second heat sink 43 can be divided into the first portion 71 and the second portion 72 of the second housing 3. Thus, the equalization of heat of the second housing 3 can be further improved.

Next, the structure of the present embodiment is explained from another point of view.

The electronic apparatus 1 of the present embodiment comprises the first housing 2, the second housing 3, the first heat sink 41, the heating component 40 housed in the first housing 2, the second heat sink 43 and the fan 45. The first housing 2 comprises the first exhaust holes 31 and the second exhaust holes 32. The second housing 3 is rotatably attached to the first housing 2, and faces the first holes 31 and the second exhaust holes 32 when the second housing 3 is raised with respect to the first housing 2. The first heat sink 41 faces the first exhaust holes 31. The second heat sink 43 is thermally connected to the heating component 40. The fan 45 comprises the first discharge hole 51 configured to discharge airflow which goes through the first heat sink 41 to the first exhaust holes 31, and the second discharge hole 52 configured to discharge airflow which goes through the second heat sink 43 to the second exhaust holes 32.

According to this structure, the heat from the first heat sink 41 and the heat from the second heat sink 43 can be divided into the first portion 71 and the second portion 72 of the second housing 3. Therefore, the equalization of heat of the second housing 3 can be improved. In this manner, the cooling performance of the electronic apparatus 1 can be enhanced, and the reliability and lifetime of the electronic apparatus 1 can be improved.

In a case of this point of view, the first heat sink 41 may not be thermally connected to the heating component 40. As shown in FIG. 9, the first heat sink 41 may be thermally connected to the heating component 75 which is different from the heating component 40. The heating component 40 may not be directly cooled down by the airflow from the second discharge hole 52. The heating component 40 may be provided so as not to directly receive the airflow from the second discharge hole 52.

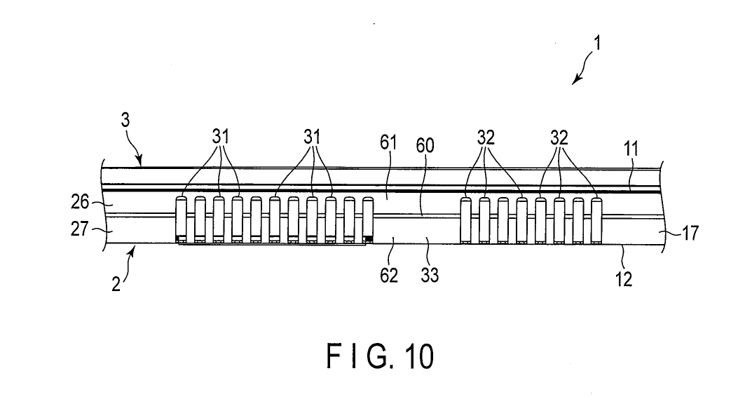

Next, with reference to FIG. 10, a modification of the first exhaust holes 31 and the second exhaust holes 32 are explained. As shown in FIG. 10, each of the first exhaust holes 31 and the second exhaust holes 32 may range from the first area 61 to the second area 62 in the rear wall 17. In other words, each of the first upper exhaust holes 31A and a corresponding first lower exhaust hole 31B may be connected to each other to be formed as one hole. Similarly, each of the second upper exhaust holes 32A and a corresponding second lower exhaust hole 32B may be connected to each other to be formed as one hole. This modification is applicable to the electronic apparatus 1 of all of the standpoints described above.

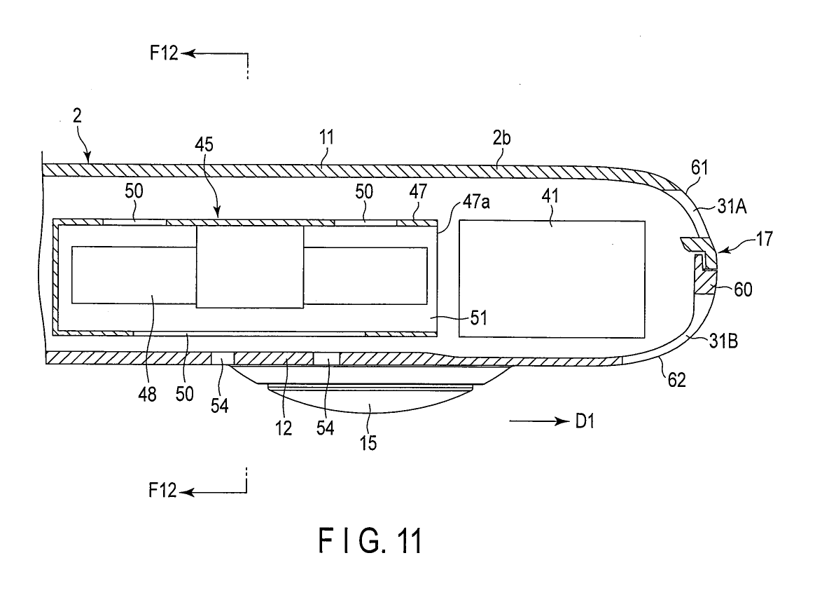

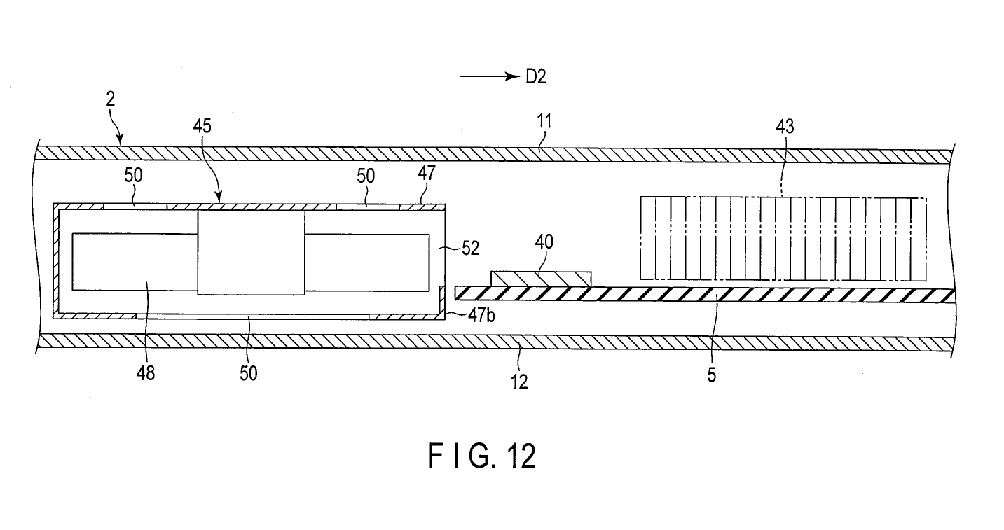

Next, a modification of the fan 45 is explained with reference to FIG. 11 and FIG. 12. As shown in FIG. 11, the first discharge hole 51 is provided in substantially the whole area of the first lateral surface 47a of the fan case 47. On the other hand, as shown in FIG. 12, the second discharge hole 52 is provided in a part (e.g., the upper half portion) of the second lateral surface 47b of the fan case 47 in such a way that the second discharge hole 52 faces only the space above the circuit board 5.

According to this structure, it is possible to effectively send airflow from the second discharge hole 52 to the heating component 40, and thus, the cooling performance of the electronic apparatus 1 can be improved. This modification is applicable to the electronic apparatus 1 of all of the standpoints described above.

In the above descriptions, one embodiment and its modifications are explained. However, the present invention is not limited to the embodiment and modifications. The structures related to the above embodiment and modifications can be implemented by appropriate modification, exchange or combination.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a first housing comprising a first exhaust hole and a second exhaust hole;
a heating component in the first housing;
a first heat sink facing the first exhaust hole;
a first heat pipe thermally connecting the heating component and the first heat sink; and
a fan comprising a first discharge hole configured to create airflow passing the first heat sink and going to the first exhaust hole, and a second discharge hole configured to create airflow passing a circumference of the heating component and going to the second exhaust hole.

2. The electronic apparatus of claim 1, further comprising a second heat sink facing the second exhaust hole, wherein
the second discharge hole is configured to create airflow going to the second heat sink and the second exhaust hole after passing the circumference of the heating component.

3. The electronic apparatus of claim 2, further comprising a second heat pipe thermally connecting the heating component and the second heat sink.

4. The electronic apparatus of claim 2, further comprising a second housing rotatably attached to the first housing, wherein
the first housing comprises a first wall, a second wall opposite to the first wall, and a third wall extending from the first wall to the second wall and configured to face the second housing when the second housing is raised with respect to the first housing, and
the first exhaust hole and the second exhaust hole are provided in the third wall, and configured to face the second housing when the second housing is raised with respect to the first housing.

5. The electronic apparatus of claim 4, wherein
the third wall comprises an outmost portion projecting in a direction from the fan outward, a first area obliquely extending between the outmost portion and the first wall, and a second area obliquely extending between the outmost portion and the second wall, and
the first exhaust hole comprises a portion located in one of the first area and the second area, and the second exhaust hole comprises a portion located in the other one of the first area and the second area.

6. The electronic apparatus of claim 4, wherein
the first heat sink and the second heat sink are provided at positions shifted from each other along a direction from the first wall to the second wall.

7. The electronic apparatus of claim 4, wherein
the second discharge hole opens in a direction different from the first discharge hole.

8. The electronic apparatus of claim 7, further comprising a guide in the first housing, the guide being configured to guide airflow created from the second discharge hole and passing the circumference of the heating component, toward the second exhaust hole.

9. An electronic apparatus comprising:
a first housing comprising a first exhaust hole and a second exhaust hole;
a second housing rotatably attached to the first housing, and configured to face the first exhaust hole and the second exhaust hole when the second housing is raised with respect to the first housing;
a first heat sink facing the first exhaust hole;
a heating component in the first housing; and
a fan comprising a first discharge hole configured to create airflow passing the first heat sink and going to the first exhaust hole, and a second discharge hole configured to create airflow passing a circumference of the heating component and going to the second exhaust hole.

10. The electronic apparatus of claim 9, further comprising a second heat sink facing the second exhaust hole, wherein
the second discharge hole is configured to create airflow going to the second heat sink and the second exhaust hole after passing the circumference of the heating component.

11. The electronic apparatus of claim 10, wherein
the first housing comprises a first wall, a second wall opposite to the first wall, and a third wall extending from the first wall to the second wall and configured to face the second housing when the second housing is raised with respect to the first housing, and
the first exhaust hole and the second exhaust hole are in the third wall.

12. The electronic apparatus of claim 11, wherein
the third wall comprises an outmost portion projecting in a direction from the fan outward, a first area obliquely extending between the outmost portion and the first wall, and a second area obliquely extending between the outmost portion and the second wall, and
the first exhaust hole comprises a portion located in one of the first area and the second area, and the second exhaust hole comprises a portion located in the other one of the first area and the second area.

13. The electronic apparatus of claim 11, wherein
the first heat sink and the second heat sink are provided at positions shifted from each other along a direction from the first wall to the second wall.

14. An electronic apparatus comprising:
a first housing comprising a first exhaust hole and a second exhaust hole;
a second housing rotatably attached to the first housing, and configured to face the first exhaust hole and the second exhaust hole when the second housing is raised with respect to the first housing;
a first heat sink facing the first exhaust hole;
a heating component in the first housing;
a second heat sink thermally connected to the heating component; and
a fan comprising a first discharge hole configured to create airflow passing the first heat sink and going to the first exhaust hole, and a second discharge hole configured to create airflow passing the second heat sink and going to the second exhaust hole.

15. The electronic apparatus of claim 14, wherein
the first housing comprises a first wall, a second wall opposite to the first wall, and a third wall extending from the first wall to the second wall and configured to face the second housing when the second housing is raised with respect to the first housing, and
the first exhaust hole and the second exhaust hole are in the third wall.

16. The electronic apparatus of claim 15, wherein
the third wall comprises an outmost portion projecting in a direction from the fan outward, a first area obliquely extending between the outmost portion and the first wall, and a second area obliquely extending between the outmost portion and the second wall, and
the first exhaust hole comprises a portion located in one of the first area and the second area, and the second exhaust hole comprises a portion located in the other one of the first area and the second area.

17. The electronic apparatus of claim 15, wherein
the first heat sink and the second heat sink are provided at positions shifted from each other along a direction from the first wall to the second wall.
